(19) United States
(12) Patent Application Publication
(10) Pub. No.: US 2025/0333833 A1
(43) Pub. Date: Oct. 30, 2025

(54) GRAPHENE VAPOR DEPOSITION SYSTEM AND PROCESS

(71) Applicant: Richard Tracy McDaniel, Wright City, MO (US)

(72) Inventor: Richard Tracy McDaniel, Wright City, MO (US)

(21) Appl. No.: 19/262,523

(22) Filed: Jul. 8, 2025

Related U.S. Application Data
(63) Continuation-in-part of application No. 18/187,908, filed on Mar. 22, 2023, now Pat. No. 12,385,129.
(60) Provisional application No. 63/366,776, filed on Jun. 22, 2022.

(51) Int. Cl. C23C 14/00; C23C 14/06; C23C 14/24; C23C 14/50; C23C 14/54; C25D 7/06

(52) U.S. Cl. CPC C23C 14/0005; C23C 14/0605; C23C 14/24; C23C 14/50; C23C 14/54; C25D 7/0614

(57) ABSTRACT

A graphene vapor deposition system and method produce high-quality graphene films. The system includes a substrate supply with a copper sheet or copper-plated metal sheet, a vacuum housing, a hydraulic actuator, a pump, and a heating device to vaporize a carbon source for graphene deposition. A dissolving tank removes the copper substrate, yielding a free-standing graphene film. Automated components, such as robotic arms and a control system, enhance scalability and efficiency. The method involves positioning the substrate, creating a vacuum, vaporizing the carbon source, depositing graphene, and dissolving the copper substrate. Operating at about 600° C. to about 900° C., the process supports iterative deposition for improved uniformity. This system and method enable scalable, cost-effective graphene production for industrial applications.

### CROSS-REFERENCE TO RELATED APPLICATION

This application is a continuation-in-part of U.S. application Ser. No. 18/187,908, filed Mar. 22, 2023, the contents of which are herein incorporated by reference. application Ser. No. 18/187,908 is based upon U.S. provisional application Ser. No. 63/366,776 filed Jun. 22, 2022, incorporated by reference in its entirety.

### BACKGROUND OF THE DISCLOSURE

The present invention relates to graphene production technologies and, more particularly, to systems and methods for graphene vapor deposition.

Graphene is a two-dimensional material having a beehive-like lattice arrangement formed by carbon hybrid orbitals. Graphene is optically transparent and has extraordinarily high thermal conductivity and electron mobility properties at room temperature (i.e., from about 68 to 72 degrees Fahrenheit) as well as atomic levels of low thickness and high mechanical strength. These exceptional properties have provided graphene with unique, extensive industrial applicability in the functioning of products including photonic and electronic parts, fuel cells, electrochemical products, sensory devices, field emission, hydrogen storage, and power-supplying materials.

The drive to integrate superior materials into cutting-edge devices has led to a focus on achieving scalable, high-quality synthesis processes. Industries in electronics, sensors, and energy solutions are increasingly dependent on materials that can meet stringent performance standards while also being produced efficiently. Variability in thermal management, surface treatment, and process integration can lead to defects, non-uniform film formation, and decreased material performance.

Currently known methods of producing graphene include, for example, the following: (1) in a separation method, individual graphene plates are separated from a graphite crystal by mechanical or chemical means and their combination; and the size of assorted graphene plates synthesized from this method generally tend to be smaller than a graphite crystal; therefore, they are not suitable for use in large-area applications; (2) in another method, silicon carbide is heated to a high temperature to remove silicon, which results in single-layer or multilayer graphene; however, graphene made by this method cannot be adapted for uses on non-silicon carbide substances; moreover, it can cause problems when required to produce large area graphene sheets of uniform thickness; (3) chemical vapor deposition is currently the most popular, known preparation method for making graphene; yet, an inclination to produce monolayer and multilayer polycrystalline graphene having island-like, small crystalline domains and grain boundaries, make it difficult to achieve flat mono layer graphene having large crystalline domains, or large area monolayer graphene sheet.

As can be seen, there is a need for a process for producing flat, mono layer graphene having large crystalline domains or large area monolayer graphene sheets efficiently.

### SUMMARY OF THE INVENTION

In a first aspect, a graphene vapor deposition system comprises a substrate supply that provides at least one substrate selected from a copper sheet or a copper-plated metal sheet, a supporting surface to hold the substrate, and a housing defining an interior region. The housing includes a sealing surface configured to engage the supporting surface to maintain vacuum conditions. A hydraulic actuator moves the housing from an elevated position to one that urges the sealing surface against the supporting surface to form a vacuum-tight seal. A pump evacuates the interior region to a predetermined vacuum level, while a carbon source disposed within the interior region is vaporized by a heating device to enable graphene deposition on the substrate. A nearby dissolving tank receives the substrate after deposition to dissolve the copper and obtain a free-standing graphene film. In various implementations, the system further includes a control system to coordinate operation of the hydraulic actuator, pump, and heating device; mobile components such as a dissolving tank, an electroplating tank, or a mobile plate holding table to reposition the substrate; and a robotic arm for transferring the substrate among the supporting surface, electroplating tank, and dissolving tank. Additional features may include a housing built from multiple units, automated, computer-controlled, chain-driven mobile components, and a secondary heating device to maintain a set temperature within the housing.

In another aspect, a method of synthesizing a graphene sheet by vapor deposition is provided. The method comprises providing a copper substrate and a carbon source, positioning the substrate on a supporting surface, and lowering a vacuum housing with a sealing surface onto the supporting surface by actuating a hydraulic mechanism to create a vacuum-tight seal. Once the interior region of the housing is evacuated to a predetermined vacuum level, a heat source vaporizes the carbon source, thereby depositing a layer of graphene on the copper substrate. The graphene-coated substrate is then transferred into a dissolving tank containing a copper-dissolving liquid, and the copper is dissolved to release a free-standing graphene film. In some embodiments, the method further includes heating the interior region to temperatures ranging from about 600° C. to about 900° C., optionally opening a vacuum release valve and raising the housing prior to transfer, followed by repeating the evacuation, heating, and vaporizing steps; electroplating a metal sheet with copper in an adjacent electroplating tank to form the copper substrate; and, after dissolving the copper, separating the graphene film from the copper-dissolving liquid.

These and other features, aspects and advantages of the present invention will become better understood with reference to the following drawings, description, and claims.

### BRIEF DESCRIPTION OF THE DRAWINGS

FIG. 1 presents an exploded view of the components of a system and process for producing graphene according to principles of the present subject matter;

FIG. 2 is a cross-sectional, side elevational view of a graphene-producing plated feature of the present subject matter, on an enlarged scale relative to FIG. 3;

FIG. 3 is a side elevational view, partially in section, of the system and process for producing graphene according to principles of the present subject matter;

FIG. 4 is a cross-sectional, side elevational view of a feature of the present subject matter shown in FIG. 2, with graphene particles now formed thereon;

FIG. 5 is another cross-sectional, side elevational view of the subject matter shown in FIG. 4, after its transfer into a metal (e.g., copper) dissolving tank;

FIG. 6 is a diagram of an illustrative process presenting exemplary steps for producing graphene in accordance with principles of the present subject matter; and

FIG. 7 is an exploded view of the components of a graphene production system according to another embodiment of the present invention.

### DETAILED DESCRIPTION OF THE INVENTION

The following detailed description is of the best currently contemplated modes of carrying out exemplary embodiments of the invention. The description is not to be taken in a limiting sense but is made merely for the purpose of illustrating the general principles of the invention, since the scope of the invention is best defined by the appended claims.

Broadly, one embodiment of the present invention is a graphene vapor deposition system and method that utilizes a copper sheet or copper electroplated onto a metal sheet as a substrate. The system integrates a vacuum housing with at least one heating source, and a dissolving tank into a cohesive workflow. This integration streamlines the production process, reduces variability, and enhances the uniformity of graphene deposition. By employing a dedicated heating source to vaporize carbon within a controlled vacuum environment, the described system ensures efficient and consistent graphene formation. Furthermore, the inclusion of mobile and automated components, such as a robotic arm and chain-driven tanks, enhances scalability and operational efficiency, making the process more adaptable to industrial-scale production.

Graphene produced by a system or apparatus according to embodiments of the present subject matter could be produced using subtractive manufacturing techniques. For instance, graphene produced by a system or apparatus according to embodiments of the present subject matter could be formed to a predetermined shape or size to optimize efficiency. The graphene could next be laser cut, to size. Hydraulics, lasers, heat sources, carbon, vacuum pumps, and conveyors may be purchased from commercial sources. To create a vacuum seal, please refer to “How to make a vacuum seal” on YouTube. Suitable vacuum seals are heat resistant.

In some embodiments, mobile robotic arms on guide tracks may be used to transfer plates through the production process. A mobile plating tank and a mobile plate stacking table, a mobile dissolving fluid tank and a mobile vacuum plate holder table may be automated, computer controlled, and chain driven. For example, a large robotic arm may be used to transfer a plate into an automated electro-plating tank under a vacuum housing and to transfer it to a vacuum press table (or vice versa). Carbon may form on the plate on the vacuum table. The large robotic arm may transfer the carbonized plate onto a dissolving tank to remove carbon. the dissolving tank may be fitted with anti-sloshing guards. The large robotic arm may stack clean vacuum plates onto a plate holding table and may place the clean vacuum plates onto the electro-plating tank. Once the plate holding table is full, it may move autonomously or manually to a position in which the robotic arm can transfer plates from the stacking table to the electroplating tank. The electro-plating tank may be mounting on a mobile table that may move into line for plating and may move out of the way for a subsequent plating tank to move into position. In some cases, dozens of automated plating tanks may take turns moving into position. Small robotic arms may be used to place carbon and/or radioactive blocks (e.g., nuclear batteries) onto a carbon holder. This approach can reduce human error and enhance processing efficiency.

A copper sheet or a copper-plated metal sheet generally serves as the substrate for graphene formation. During the vapor deposition process, graphene is synthesized directly onto the exposed copper surface, which may be either a solid copper sheet or a copper layer electroplated onto a base metal that is resistant to the copper-dissolving solution. After the graphene layer has been deposited, the copper substrate is selectively dissolved in a copper-dissolving liquid, such as nitric acid or another suitable etchant, within a dissolving tank. This process effectively separates the graphene film from the underlying metal, enabling the recovery of a free-standing graphene sheet. The use of a copper-plated metal sheet not only reduces material costs but also facilitates the efficient and scalable production of high-quality graphene films, as the base metal remains intact and can be reused or further processed.

The carbon source utilized in the graphene vapor deposition process can be derived from any carbon-containing material, providing significant flexibility and cost efficiency in material selection. Examples of suitable carbon sources include, but are not limited to, household waste, trash, garbage, carbon powder, and other carbon-rich substances. This versatility allows the process to leverage readily available or low-cost materials, reducing the overall production expenses while maintaining the quality of the graphene produced. During the deposition process, the selected carbon source is vaporized within the vacuum housing using a heating means, such as a laser or other high-intensity heat source, to generate carbon vapor. This vapor subsequently bonds to the copper substrate, forming a uniform graphene layer. The ability to use diverse carbon sources, including waste materials, not only enhances the economic viability of the process but also contributes to environmental sustainability by repurposing otherwise discarded materials.

In embodiments, the heat source for localized vaporization of the carbon source within the vacuum housing comprises a laser system. The laser system includes one or more high-intensity laser emitters positioned to direct focused laser beams onto the carbon source. The use of lasers as the heating means provides precise and localized heating, enabling efficient conversion of the carbon source into vaporized carbon. This approach minimizes thermal losses and ensures uniform carbon vaporization, which enables consistent graphene deposition on the copper-plated substrate. Additionally, the laser system can be controlled via the integrated control system to adjust parameters such as beam intensity, duration, and focus, allowing for fine-tuned process optimization. In embodiments, the system may also use a secondary heating source for temperature control within the vacuum housing, for example to control interior temperature to the most efficient setting for graphene production.

The described system and method leverage electroplated copper substrates, integrated process steps, and advanced heating mechanisms to achieve significant cost reductions—estimated to be as low as one-twentieth to one-fiftieth of prior art methods—while delivering high-quality graphene films.

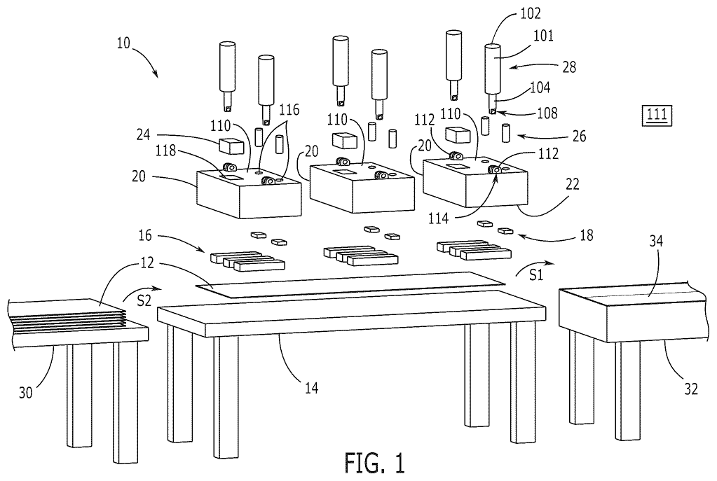

Referring now to FIGS. 1-7, FIG. 1 illustrates a graphene production system 10 according to one embodiment, including an elongated table 14 serving as a supporting surface for an elongated copper-plated sheet of metal 12. Disposed above the copper-plated sheet 12 are a plurality of vacuum housings 20, each associated with a pair of hydraulic cylinders 28. Each hydraulic cylinder 28 features a main body portion 101, a first end portion 102 secured to a press frame (not shown), and a second end portion 104 that is extendable and retractable. The distal end of the second end portion 104 includes a through bore 108, which aligns with a through bore 114 in a mount 112 on the upper surface 110 of each vacuum housing 20, allowing a pin to secure the hydraulic cylinders to the vacuum housings.

The system 10 further includes a plurality of heating sources 16 for heating an interior of the housing and carbon trays 18 positioned between the copper-plated sheet 12 and the vacuum housings 20, with three heating sources and two carbon trays beneath each vacuum housing. Above the vacuum housings 20, a plurality of vacuum pumps 24 and heating sources 26 for vaporizing carbon are shown, with the upper surface 110 of each vacuum housing 20 defining through bores 116 for receiving the heating sources 26 and a recess 118 for accommodating a vacuum pump 24.

The copper-plated sheet 12 is transferred S2 to the supporting surface 14 from a mobile plate holding table 30 and is transferred S1 from the supporting surface 14 to the dissolving tank 32. The vacuum housing 20 defines an interior region 120 and includes a sealing surface 22 that engages the supporting surface 14 to maintain vacuum conditions. The hydraulic cylinder 28 moves the vacuum housing 20 between raised and lowered positions, enabling the sealing surface 22 to form a vacuum-tight seal with the supporting surface 14. A pump 24 evacuates the interior region 120 to achieve the required vacuum for graphene deposition.

Within the vacuum housing 20, a heating source 26 vaporizes the carbon source 18, enabling graphene deposition on the copper-plated sheet 12. The system includes a control system 111 operatively connected to the pump 24, a heating source 16 for heating the region within the vacuum housing, and heating source 26 for vaporizing carbon, ensuring precise regulation of temperature and vacuum levels. A dissolving tank 32, positioned adjacent to the supporting surface 14, contains a copper-dissolving liquid 34 for separating the graphene layer from the copper substrate after deposition.

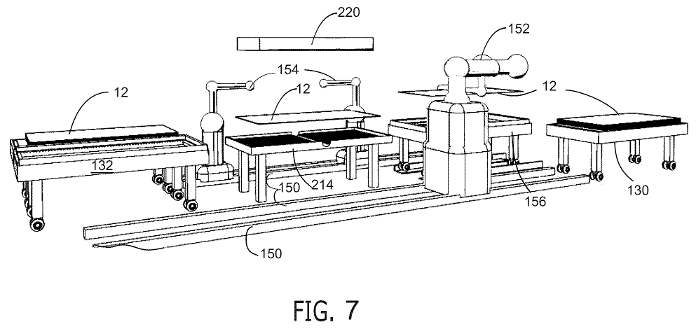

Additional system components include sensors (not shown) for monitoring temperature, pressure, and other parameters, all integrated with the control system 111. In embodiments, a mobile robotic arm 152 or 154 (see FIG. 7) may be used to transfer the copper-plated sheet 12 among the supporting surface 14, vacuum housing 20, and dissolving tank 32, enhancing automation and operational efficiency.

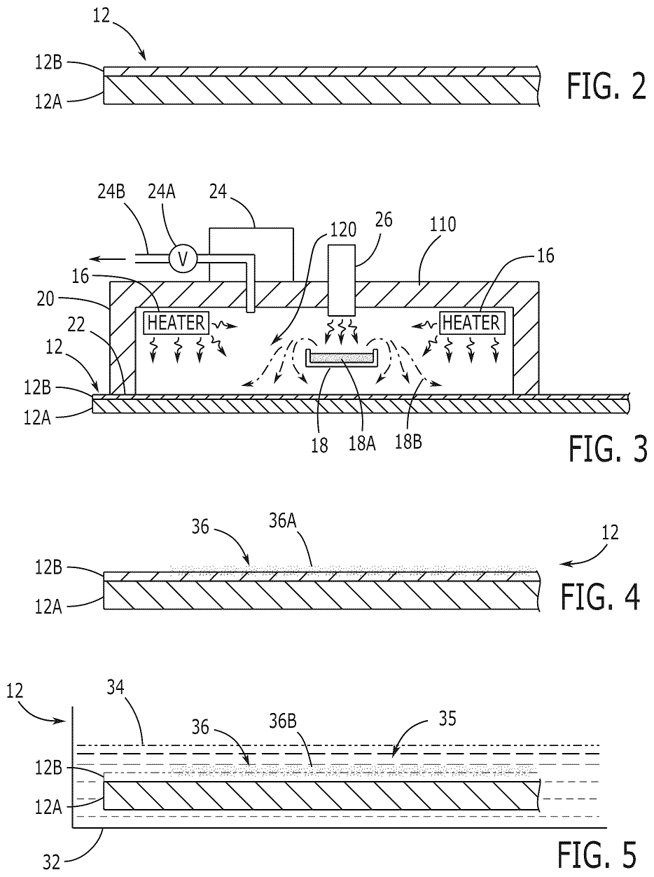

Turning to FIG. 2, the copper-plated sheet 12 used as the substrate for graphene deposition features a distinct layered structure comprising a base sub-layer 12A and an upper copper sub-layer 12B. The base sub-layer 12A is typically formed from a metal or alloy that is resistant to dissolution in acids such as nitric acid or sulfuric acid, providing mechanical stability and compatibility with the electroplating process. Examples of suitable materials for sub-layer 12A include precious metals like gold, platinum, and palladium, which do not dissolve in concentrated nitric acid, as well as certain non-precious metals such as iron, nickel, chromium, and aluminum, which form protective oxide layers that inhibit acid attack. The copper sub-layer 12B is electroplated onto the base sub-layer 12A, such as a metal sheet, serving as the active surface for graphene growth. This electroplated copper layer enables precise control over graphene thickness and uniformity, reduced material costs, and efficient separation of free-standing graphene films.

The copper sub-layer 12B provides the necessary catalytic properties for chemical vapor deposition (CVD) of graphene, facilitating efficient carbon atom bonding and layer formation. The use of an electroplated copper layer, as opposed to traditional copper foils, not only reduces material costs but also allows for customization of substrate properties such as surface roughness and thermal conductivity, thereby optimizing the graphene synthesis process. The integrated structure of sub-layers 12A and 12B ensures both durability and adaptability for industrial-scale graphene production.

As shown in FIG. 3, the graphene vapor deposition system is configured to facilitate the controlled synthesis of graphene on a copper-plated sheet 12. The system includes a vacuum housing 20 that defines an interior region 120 and is equipped with a vacuum seal 22 along its underside surface to ensure airtight conditions during operation. The vacuum housing 20 is positioned above the copper-plated sheet 12 and is actuated by hydraulic cylinders 28, which lower the housing to form a vacuum-tight seal against the upper copper layer 12B of the substrate.

Within the interior region 120 of the vacuum housing 20, carbon trays 18 are arranged at a predetermined distance above the copper-plated sheet 12. Each carbon tray 18 holds a block 18A of carbon powder, which serves as the carbon source for graphene formation. The system is further equipped with heating sources 16, 26, both of which are powered by an external source. The carbon vaporization heating source 26 may be a laser or laser system, for example. When the vacuum pumps 24, connected via evacuation lines 24B and controlled by open/close valves 24A, sufficiently evacuate the interior region 120, the heaters 26 are activated, causing the carbon powder 18A to vaporize into carbon vapor 18B. The heaters 16 may be activated prior to activating the heaters 26 to raise the temperature within the vacuum housing if the ambient temperature falls below a predetermined threshold.

The vaporized carbon then deposits onto the exposed copper surface 12B, initiating the formation of graphene deposits 36A. This initial deposition results in the formation of discrete graphene deposits 36A on the copper surface. As the process continues, these graphene deposits 36A grow and merge, ultimately coalescing into a continuous graphene layer 36 that uniformly covers the upper copper sub-layer 12B, as seen in FIG. 4. The arrangement of heating elements, carbon source, and vacuum control within the housing ensures efficient and uniform graphene growth, while the hydraulic actuation and vacuum sealing mechanisms maintain the necessary process environment for high-quality graphene synthesis uniformly across the substrate.

Referring now to FIG. 5, the illustration depicts the stage in which the copper sub-layer 12B of the copper-plated sheet has been completely dissolved by the acid solution 34 within the dissolving tank 32. As a result, a free-standing sheet of graphene 36B remains, separated from the underlying base metal. The recovered graphene 36B is of commercial and industrial quality, suitable for being rolled, stored, or shipped as needed for downstream applications. The system 10, under the management of the operational control system 111, coordinates the dissolution process and subsequent handling of the graphene, ensuring efficient production and reliable recovery of high-quality graphene films.

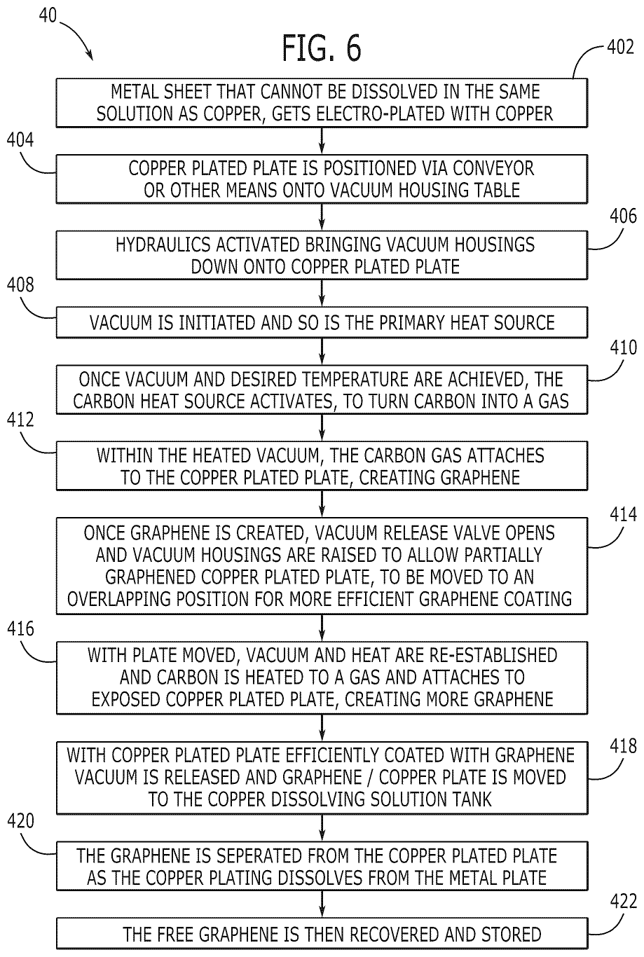

FIG. 6 provides a flowchart that illustrates the sequential steps of the graphene vapor deposition process 40. The process begins at step 402, where a metal sheet that is resistant to dissolution in copper-dissolving solutions is electroplated with copper to form a copper-plated plate. At step 404, the copper-plated plate is positioned onto a vacuum housing table using a conveyor or other suitable means. In step 406, hydraulic cylinders are actuated to lower the vacuum housing onto the plate, creating a sealed environment. Step 408 involves initiating vacuum conditions within the housing and powering on the primary heat source to raise the temperature. Once the desired vacuum and temperature are achieved, as indicated in step 410, a secondary heat source is activated to vaporize the carbon material.

At step 412, the vaporized carbon attaches and condenses on the copper surface, forming a graphene layer. After initial graphene formation, step 414 calls for opening the vacuum release valve and moving the vacuum housing to an overlapping position, allowing for more efficient and uniform graphene coverage. The hydraulic actuation provided by the present system enables rapid sealing/unsealing. Alternatively, the table or support may be moved and/or the carbon source/heating assembly may be moved to enable deposition on overlapping positions. This iterative deposition with intermediate substrate movement improves graphene coverage and reduces defects. Step 416 involves re-establishing vacuum and temperature conditions, followed by additional carbon vaporization and graphene deposition on any exposed areas. Once the copper-plated plate is efficiently coated with graphene, step 418 directs the release of the vacuum and the transfer of the graphene-coated plate to a copper-dissolving tank 32. In step 420, the copper plating is dissolved, separating the graphene from the underlying metal plate. Finally, at step 422, the free-standing graphene is recovered and stored, resulting in high-quality graphene ready for further application.

Referring to FIG. 7, an alternate embodiment of the graphene vapor deposition apparatus is illustrated, emphasizing automation and enhanced material handling. The system features a large mobile robotic arm 152 mounted on guide tracks 150, which is configured to transfer copper-plated sheets 12 between various processing stations. The robotic arm 152 moves plates 12 from a mobile table 130 into an automated electroplating tank 156 for copper deposition, then transfers the plated sheets 12 to a vacuum press table 214 positioned under a vacuum housing 220 for graphene deposition. Small robotic arms 154 for place carbon sources 18A and/or radioactive blocks onto carbon holders 18. After graphene formation, the robotic arm 152 moves the carbonized plate 12 to a dissolving tank 132 for copper removal and graphene recovery.

The mobile plate holding table 130 can be repositioned to facilitate efficient transfer of plates to the electroplating tank 156. The electroplating tank 156 itself is mobile, allowing it to move into position for plating or out of the way for subsequent tanks, supporting high-throughput and scalable operation. Chain-driven tracks 150 synchronize the movement of mobile components such as the plate holding table 130 and dissolving tank 132, further improving operational efficiency.

The foregoing description relates to illustrative embodiments of a graphene vapor deposition system and process. However, the invention is not limited to these specific examples. Various alternatives, modifications, and changes will be apparent to those skilled in the art upon review of this application and its figures. Such alternatives and modifications are intended to be included within the scope of the invention, provided they fall within the spirit and scope of the appended claims.

What is claimed is:

1. A graphene vapor deposition system comprising:
a substrate supply comprising at least one substrate selected from the group consisting of a copper sheet and a copper-plated metal sheet;
a supporting surface for supporting the substrate;
at least one housing defining an interior region, the at least one housing including a sealing surface configured to engage the supporting surface to maintain vacuum conditions within the interior region;
a hydraulic actuator operatively coupled to the at least one housing and configured to move the at least one housing between a first position suspended above the supporting surface and a second position urging the sealing surface against the supporting surface to provide a vacuum-tight seal;
a pump operatively connected to the at least one housing for evacuating the interior region to a predetermined vacuum level;
a carbon source disposed within the interior region;
a heating device configured to vaporize the carbon source to enable graphene vapor deposition on the substrate; and
a dissolving tank positioned adjacent to the at least one housing and configured to receive the substrate after graphene deposition and to dissolve the copper to obtain a graphene film.

2. The graphene vapor deposition system of claim 1, further comprising a control system operatively connected to the hydraulic actuator, the pump, and the heating device.

3. The graphene vapor deposition system of claim 1, further comprising mobile components selected from the group consisting of the dissolving tank, an electroplating tank, and a mobile plate holding table operative to move the substrate from a first plate position to a second plate position.

4. The graphene vapor deposition system of claim 1, further comprising a mobile robotic arm operative to transfer the substrate to and from the supporting surface.

5. The graphene vapor deposition system of claim 1, wherein the at least one housing comprises at least two housings.

6. The graphene vapor deposition system of claim 3, wherein the mobile components are automated, computer-controlled, and chain driven.

7. The graphene vapor deposition system of claim 4, wherein the mobile robotic arm is operative to transfer a metal sheet into an electroplating tank to produce the copper-plated metal sheet; and to transfer the copper-plated metal sheet to the supporting surface and from the support surface into the dissolving tank.

8. The graphene vapor deposition system of claim 1, further comprising a secondary heating device to maintain a predetermined temperature threshold within the housing.

9. A method of synthesizing a graphene sheet by vapor deposition, comprising:
providing the graphene vapor deposition system of claim 1;
positioning the substrate on the supporting surface;
lowering the housing onto the supporting surface by actuating the hydraulic actuator to establish a vacuum-tight seal;
evacuating the interior region of the at least one housing with the pump;
vaporizing the carbon source by activating the heating device;
depositing a layer of graphene on the substrate by exposing the substrate to the vaporized carbon;
transferring the graphene-coated substrate into the dissolving tank containing a copper-dissolving liquid; and
dissolving the substrate in the dissolving tank to release and recover the graphene film.

10. The method of claim 9, further comprising heating the interior region to a temperature ranging from about 600° C. to about 900° C.

11. The method of claim 9, further comprising:
prior to transferring the graphene-coated copper substrate into the dissolving tank, opening a vacuum release valve and raising the vacuum housing; and
repeating the steps of evacuating the interior region, heating the interior region, and vaporizing the carbon source.

12. The method of claim 9, further comprising electroplating a metal sheet with copper to form the copper substrate in an electroplating tank positioned adjacent to the supporting surface.

13. The method of claim 9, further comprising, after dissolving the copper in the dissolving tank, separating the free-standing graphene film from the copper-dissolving liquid.
